(19) United States
(12) Patent Application Publication
(10) Pub. No.: US 2016/0027995 A1
(43) Pub. Date: Jan. 28, 2016

(54) METHOD FOR PRODUCING A MULTILAYER ELECTROMECHANICAL TRANSDUCER

(71) Applicants: BAYER MATERIAL SCIENCE AG, Leverkusen (DE); HOCHSCHULE OSTWESTFALEN LIPPE, Lemgo (DE)

(72) Inventors: Joachim WAGNER, Köln (DE); Jens KRAUSE, Leverkusen (DE); Christian GRAF, Ingolstadt (DE); Dennis CORDING, Herford (DE); Jürgen MAAS, Detmold (DE); Dominik TEPEL, Medebach-Dreislar (DE); Thorben HOFFSTADT, Lemgo (DE)

(21) Appl. No.: 14/761,026

(22) PCT Filed: Jan. 13, 2014
(86) PCT No.: PCT/EP2014/050442

§ 371 Date: Jul. 15, 2015

(30) Foreign Application Priority Data
Jan. 16, 2013 (EP) 13151523.1

(51) Int. Cl. H01L 41/27; H01L 41/297; H01L 41/09; H02N 11/00; H01L 41/08

(52) U.S. Cl. CPC H01L 41/27; H02N 11/002; H01L 41/0805; H01L 41/09; H01L 41/297

(57) ABSTRACT

The invention relates to a process for the production of at least one multilayer electromechanical transducer (44), comprising provision of at least one dielectric elastomer foil (10, 16, 22, 30, 46), application of at least one electrode layer (12, 18, 20, 24, 26, 28, 42) to at least one first part (16.1, 16.4, 22.1) of the elastomer foil (10, 16, 22, 30, 46) in an application step, arrangement of the elastomer foil (10, 16, 22, 30, 46) on a receptor area (4) of a folding apparatus (2), where the folding apparatus (2) has a first plate (2.1) and a second plate (2.2), fixing of the elastomer foil (10, 16, 22, 30, 46) on the receptor area (4), and folding of the first part (16.1, 16.4, 22.1) of the elastomer foil (10, 16, 22, 30, 46) onto another part (16.2, 16.3, 22.3) of the elastomer foil (10, 16, 22, 30, 46) in a folding step via folding of the first plate (2.1) in relation to the second plate (2.2) in such a way that the electrode layer (12, 18, 20, 24, 26, 28, 42) is arranged between the first part (16.1, 16.4, 22.1) of the elastomer foil (10, 16, 22, 30, 46) and the second part (16.2, 16.3, 22.3) of the elastomer foil (10, 16, 22, 30, 46).

The invention relates to a method for producing a multilayer electromechanical transducer, an electromechanical transducer, a component comprising the electromechanical transducer, a use of the electromechanical transducer and a device for producing the electromechanical transducer.

Electromechanical transducers convert electrical energy into mechanical energy and vice versa. They can be used as a component part of sensors, actuators and/or generators.

The basic construction of such a transducer consists of electroactive polymers (EAP). The principle of construction and the mode of action are similar to those of an electrical capacitor. A dielectric is present between two conductive plates, that is to say electrodes, to which a voltage is applied. However, EAPs are an extensible dielectric which deforms in a way depending on the electrical field. More specifically, they are dielectric elastomers, usually in the form of films (DEAP; dielectric electroactive polymer), which have high electrical resistivity and are coated on both sides with extensible electrodes of high conductivity (electrode), as described, for example, in WO 01/006575. This basic construction can be used in a wide variety of different configurations for the production of sensors, actuators or generators. As well as single-layer constructions, multilayer electromechanical transducers are also known.

Depending on the application, such as an actuator, a sensor and/or a generator, electroactive polymers as an elastic dielectric in such transducer systems have different electrical and mechanical properties.

The electrical properties they share are a high internal electrical resistance of the dielectric, a high dielectric strength, a high electrical conductivity of the electrode and a high dielectric constant in the frequency range of the application. These properties allow long-term storage of a large amount of electrical energy in the volume filled with the electroactive polymer.

Shared mechanical properties are sufficiently high elongation at break, low permanent elongations and sufficiently high compressive/tensile strengths. These properties ensure sufficiently high elastic deformability without mechanical damage to the energy transducer.

For electromechanical transducers that are operated “under tension”, i.e. are subjected to tensile stress during operation, it is particularly important that these elastomers do not have any permanent elongation. In particular, no flow or “creep” should occur, since otherwise, after a certain number of cycles of elongations, there is no longer any mechanical restoring force, and consequently there is no longer any electroactive effect. Therefore, the elastomers should not display any stress relaxation under a mechanical load.

For electromechanical transducers in tension mode, elastomers of highly reversible extensibility with high elongation at break and low tensile modulus of elasticity are required. It is known from the literature for such electromechanical transducers that the extensibility to the dielectric constant and the applied voltage to the square and inversely proportional to the modulus, with the relative permittivity ∈ᵣ, the absolute permittivity ∈₀, the stiffness Y and the film thickness d with the electrical voltage U displays the elongation s_{z} according to the equation:

$${s}_{z} = \frac{{σ}_{Maxwell}}{Y} = \frac{{ɛ}_{0} \cdot {ɛ}_{r}}{Y} {( \frac{U}{d} )}^{2} .$$

The maximum possible electrical voltage is in turn dependent on the disruptive strength. A low disruptive strength has the consequence here that only low voltages can be applied. Since the square of the value of the voltage is entered in the equation for calculating the extension that is caused by the electrostatic attraction of the electrodes, the disruptive strength is preferably correspondingly high.

An equation known from the prior art for this can be found in the book by Federico Carpi, Dielectric Elastomers as Electromechanical Transducers, Elsevier, page 314, equation 30.1, and similarly also in R. Pelrine, Science 287, 5454, 2000, page 837, equation 2. The equation from the above paragraph makes clear a very important property for the operation of dielectric elastomer actuators: The lower the layer thickness d, the smaller the operating voltage of the actuators can be with the same electrical field strength. At the same time, however, the absolute deformation amplitude possible in the direction of the thickness also falls with the layer thickness.

A way out of this problem has already been shown by PELRINE et al., in an early publication from 1997: By analogy with piezoelectric stack actuators, individual layers may be stacked one on top of the other [R. E. PELRINE, R. KORNBLUH, J. P. JOSEPH and S. CHIBA. “Electrostriction of polymer films for microactuators”, in: Micro Electro Mechanical Systems, 1997. MEMS '97, Proceedings, IEEE., Tenth Annual International Workshop on (1997), p. 238-243.]. These layers are electrically connected in parallel, meaning that there is a relatively high field strength E over each layer in spite of low operating voltage U. In mechanical terms, by contrast, the actuator layers are connected in series; the individual deformations are additive. The stack demonstrated by PELRINE et al. had four layers of dielectric and electrode and was produced manually. The electrode layers preferably have a certain structure, which can be achieved by a spray mask, inkjet printing and/or a screen in the case of screen printing.

A similar effect can be achieved if the elastomer films coated with electrode layers are rolled up. In this case, the deformation forces are no longer used in the direction of the applied electrical field, but at right angles thereto. Two principles for this are known:

The company Danfoss Polypower uses corrugated EAP material to construct a coreless rolled actuator [Tryson, M., Kiil, H.-E., Benslimane, M.: Powerful tubular core free dielectric electro activate polymer (DEAP) ‘PUSH’ actuator, Electroactive Polymer Actuators and Devices (EAPAD), Proc. of SPIE Vol. 7287, 2009.]; at the EMPA [Zhang, R., Lochmatter, P., Kunz, A., Kovacs, G.: Spring Roll Dielectric Elastomer Actuators for a Portable Force Feedback Glove; Smart Structures and Materials, Proc. of SPIE Vol. 6168, 2006.] the EAP material was prestressed with the aid of an integrated helical spring. A disadvantage in the case of the last principle is the high susceptibility to mechanical defects in the EAP material. The actuator effect in the case of the coreless actuator is attributable just to the circumferentially stiff electrode

A great challenge in the production of a stack actuator or a multilayer electromechanical transducer in the case of all methods is the faultless and contamination-free stacking of a multitude of dielectric layers and electrode layers. CARPI et al. identified the cutting-open of a tube as a solution to this problem. The dielectric is in the form of a silicone tube. This tube is cut open in a spiral manner, then the cut faces are covered with conductive material, and these then serve as electrodes [F. CARPI, A. MIGLIORE, G. SERRA and D. DE ROSSI. “Helical dielectric elastomer actuators”, in: Smart Materials and Structures 14.6 (2005), p. 1210-1216].

CHUC et al. presented an automated process that is based in principle on the folding according to CARPI [N. H. CHUC, J. K. PARK, D. V. THUY, H. S. KIM, J. C. KOO “Multi-stacked artificial muscle actuator based on synthetic elastomer”. In: Proceedings of the 2007 IEEE/RSJ International Conference on Intelligent Robots and Systems San Diego, Calif., USA, Oct. 29-Nov. 2, 2007 (2007), p. 771.]. However, the dielectric films here are each folded only once. The stack actuators of CARPI et al. and CHUC et al. are not designed to absorb tensile forces. Since the electrostatic forces reach only from the outside to the outside of adjacent electrodes, there is the risk of delamination of the stack actuators, since no forces exist within the electrodes. KOVACS and DÜRING developed a technique for producing extremely thin carbon black layers. Electrodes produced thereby are said to consist only of one layer of primary particles. Such a monolayer builds up electrostatic forces in relation to both adjacent electrodes and, as a result, is capable of also absorbing tensile forces [G. KOVACS and L. DÜRING]. “Contractive tension force stack actuator Based on soft dielectric EAP”. In: Electroactive Polymer Actuators and Devices (EAPAD) 2009. Published by Y. BAR-COHEN and T. WALLMERSPERGER. Vol. 7287. I. San Diego, Calif., USA: SPIE, 2009, 72870A-15.].

A feature common to the stack actuator concepts of CARPI et al., CHUC et al. and KOVACS and DÜRING presented so far is that they are designed as actuating drives with large deflections and for the generation of high forces. Of these two basic configurations, stack actuators based on a 3D multilayer structure allow the most efficient conversion of electrical input energy into mechanical work because of the parallelism thus achieved by construction means between the electrical field and the direction of extension. A description of a folding process can likewise be found in DE 10 2008 002 495. A disadvantage there is that the electrode layer is flat from beginning to end, and consequently must have a very high conductivity. The respective layers must also be laid one on top of the other very exactly, which in a folding process of this type becomes increasingly more difficult with a higher number of layers. Among the reasons for this are the edge regions in bead form occurring at the folding edges of the multilayer transducer.

Multilayer actuators or multilayer transducers may be operated under extension, tension and flexure. It is also known that actuators may be additionally equipped with a restoring spring.

However, the transducers according to the prior art have three main disadvantages, which are attributable to the insufficiently adapted elastomer, the inadequate industry-based manufacturing technology and the inadequate long-term stability. A disadvantage of all the methods mentioned is that the layers (electrode layers and elastomer layers) only weakly adhere to one another and joining the structured electrode segments together in a continuous, exactly fitting manner in the processes is either only possible very slowly, and consequently unproductively, or leads to strong displacements of the active surfaces. Since high deflections require a high number of layers, the process must be able to stack them almost faultlessly one on top of the other.

Another disadvantage of the prior art is that, in the cases described, the structured electrode has to be applied in an additional step between the layers of the stack, or else directly to a large surface area. In the first case, an additional process step is necessary, preventing stacking exactly in register. In the latter case, the electrode area is so large that an extremely high conductivity is required. Although this is technically possible, such electrodes very quickly lose their conductivity after a few loading cycles involving extension, tension or flexure. A further disadvantage of the methods mentioned is that the non-polyurethane-based solutions form a layered assembly that is very weak and does not adhesively bond together. The layers are not monolithically constructed. Thus, the layers can often be taken apart after less than 100 loading cycles, i.e. a delamination of layers takes place, or the boundary layers which then form prevent the buildup of an electrostatic attraction. Such methods are also as yet unknown for polyurethane. In particular, there is a need to develop a high-speed industrial stacking process without delamination and separation of the layers, and also small, structured electrode areas, which ensure high long-term stability.

None of the approaches mentioned above of the prior art is suitable for delamination-free and faultless stacking, since no strong adhesion or even a monolithic structure of the layers is present or possible. The systems are also not produced in a continuous or repetitive process.

The unpublished patent application EP 12174858.6 describes an approach in which freshly produced polyurethane film is reacted directly thereafter with an electrode layer and repetitively again with a polyurethane layer, and so forth, in order to produce a stack actuator.

A disadvantage of the prior art is that the much less expensive and rapid roll-to-roll production of a polyurethane film, as described in unpublished patent application EP 12173770.4, is unavailable. Another disadvantage is that this is a chemical process, in which the respective layers have not reacted up to 100% conversion. The adhesion is achieved through incomplete reaction of the layers, and so also necessitates removal of the volatile, toxic isocyanates by suction in all of the steps. The object was therefore to develop a process in which the chemical process of producing the dielectric and if need be that of producing the electrode layer are separate from the mechanical stacking steps.

A disadvantage of all the methods described in the prior art is that it is not possible to produce multilayer electromechanical transducers on an elastomer basis, since, although the elastomer films produced separately in a roll-to-roll process, for example, can be rapidly joined to one another using roll-to-roll processes by wrapping and/or can be joined to one another by automatic stacking, the layers do not have strong enough adhesion to one another and delaminate.

An alternative possibility, for example for silicone films, would be to adhesively bond the layers to one another. However, a disadvantage of this is that the adhesive step is an additional step in the process, usually followed by drying. Another disadvantage here is that an additional boundary layer with different properties forms between the layers. As before, the exact joining of the respective layers one on top of the other is unresolved.

In the prior art, a pre-stretching of the elastomer layers, which leads to a greatly increased actuator effect (i.e. extension), has so far been performed exclusively by using the IPN technique. It is disadvantageous that this in turn involves a time-intensive chemical process, which is to be avoided. The object of the present invention is intended to ensure that a pre-stretching of the film is possible.

Currently available manufacturing methods are usually only designed for the manufacture of a single transducer, such as a stack actuator, which leads to considerable manufacturing times. There is therefore a need for a parallelized manufacturing process that allows the simultaneous construction of a multitude of transducers.

If the process for producing the electrode-coated elastomer film is isolated from the production of the electromechanical transducer, the tolerances that are then unavoidable during the stacking of the very soft films leads to possible electric breakdowns (shortened creepage distances), to an unwanted bending moment, which is adversely superposed on the actually desired actuator effect, and also to a failure to establish contacting of individual actuator films.

Appropriate register marks, which are as far as possible incorporated in a rigid structure (compare multi-stage ink printing processes), are intended to make the interface between chemical and mechanical manufacture such that exact positioning and stacking of the elastomer films is ensured. If the electrode is only applied during the mechanical stacking process, either optical register marks must be applied, or the method steps of electrode coating and stacking must be performed in “one setup”.

The present invention is therefore based on the object of providing a method for producing an electromechanical transducer that at least partially reduces the aforementioned disadvantages, and in particular allows improved production with lower manufacturing times and a lower failure rate.

The object deduced and presented above is achieved according to one aspect of the invention by a method according to claim 1. The method for producing at least one multilayer electromechanical transducer comprises:
providing at least one dielectric elastomer film,
applying at least one electrode layer to at least a first part of the elastomer film in an application step,
arranging the elastomer film on a receiving surface of a folding device, the folding device having a first plate and at least one second plate,
fixing the elastomer film on the receiving surface, and
folding the first part of the elastomer film onto a further part of the elastomer film in a folding step by folding the first plate with respect to the second plate in such a way that the electrode layer is arranged between the first part of the elastomer film and the second part of the elastomer film,
stacking a number of folded elastomer films to increase the overall height of the electromechanical transducer.

By contrast with the prior art, according to the teaching of the invention an improved method for producing multilayer electromechanical transducers with a low manufacturing time is provided. By carrying out fixing of the elastomer film and folding of the elastomer film in an easy way, in particular by means of a special folding device, a multilayer electromechanical transducer can be produced (virtually) faultlessly and free from contamination, by placing a plurality of dielectric layers and electrode layers exactly in register one on top of the other. In particular, industrial manufacture of multilayer electromechanical transducers can take place.

Firstly, at least one dielectric elastomer film or elastomer layer is provided. A dielectric elastomer layer preferably has a relatively high dielectric constant. In addition, a dielectric elastomer layer preferably has a high mechanical stiffness. A dielectric elastomer layer may be used in particular for an actuator application. However, dielectric elastomer layers are similarly suitable for sensor or generator applications.

Furthermore, the dielectric elastomer film may preferably comprise a material that is for example selected from the group of synthetic elastomers comprising polyurethane elastomers, silicone elastomers, acrylate elastomers (e.g. ethylene vinyl acetate), fluororubber, unvulcanized rubber, vulcanized rubber, polyurethane, polybutadiene, NBR or isoprenes and/or polyvinylidene fluoride. Preference is given to using polyurethane elastomers.

The elastomer film provided has at least a first part and a further or second part. For example, the elastomer film may be divided into essentially two parts of the same size. In an application step, at least one electrode layer is applied at least to the first part, in particular to at least an upper side of the first part. Application on both sides may also take place.

The electrode layer, that is to say an electrically conductive layer, may preferably be formed from a material that is selected from the group comprising metals, metal alloys, conductive oligomers or polymers, conductive oxides, conductive fillers and/or polymers filled with conductive fillers. Particularly suitable materials are carbon-based materials or materials based on metals, for instance silver, copper, aluminum, gold, nickel, zinc or other conductive metals and materials. The metal may preferably be applied in the form of a salt, solution, dispersion, emulsion or a precursor. The adhesion may be adjusted such that the layers in the sequence each adhere to one another.

After the application of the electrode layer or already before the application of the electrode layer, the elastomer film may be arranged on a receiving surface of a folding device. The folding device is of a plate form. In particular, the folding device has at least two plates.

According to a preferred embodiment, the first plate may be movably connected to the second plate. The first plate and the second plate may in particular be connected by way of a hinge device.

The two plates are preferably movably connected to one another by way of at least one hinge device. In particular, the two plates may be connected to one another in such a way that, in an initial position, the two plates form a (level) plane and, in an end position, the first plate lies on the second plate (or vice versa). The first plate has a first partial receiving surface and the second plate has a second partial receiving surface. If there are only two plates, the first partial receiving surface and the second partial receiving surface form the receiving surface of the folding device.

It goes without saying that the folding device may have more than two plates, the further plates being connected for example by way of a hinge device to at least one further plate and being able to have partial receiving surfaces. As an alternative or in addition to a hinge device, a strip connection may for example also be used.

The receiving surface is designed for fixing the dielectric elastomer film, in particular reversibly. In particular, the receiving surface, for example a porous plastic (for example on a Teflon basis), may be designed for creating a negative pressure, for example a vacuum, in order to fix an elastomer film arranged on the receiving surface on the folding device. For example, recesses in which a negative pressure can be created may be provided in the receiving surface. These recesses may be provided in a segmented manner for selective fixing. The fixing may be such that the first part of the elastomer film is fixed on the first partial receiving surface and at least one further part of the elastomer film is fixed on the second partial receiving surface. By performing the fixing of the film preferably by negative pressure, the elastomer film can be fixed (virtually) free from folds and subsequently be folded. The folding device is distinguished in particular by the fact that even elastomer films with a small layer thickness can be fixed reliably and (virtually) free from folds. The elastomer film may have a layer thickness of 0.1 μm to 1000 μm, preferably of 1 μm to 500 μm, particularly preferably of 5 μm to 200 μm and most particularly preferably of 10 μm to 100 μm. The elastomer film may be formed as a monolayer. The elastomer film may preferably be of a multilayer form. In particular, the elastomer film may be of a two-layer form. The multilayer form allows possible defects to be eliminated.

After the fixing of the elastomer film on the receiving surface of the at least two plates, the elastomer film is folded, in that the first plate is folded or swung with respect to the second plate. Joining of the layers one on top of the other exactly in register is made possible. If a hinge device is present, particularly a 180° pivoting movement can be performed on the basis of the at least one hinge device. For example, the first plate may be swung onto the second plate or the second plate may be swung onto the first plate. A connection between the plates is not absolutely necessary here. This may take place in particular in such a way that the electrode layer is arranged essentially between the first part of the elastomer film and the second part of the elastomer film. In other words, at least one electrode layer is covered on both sides with an elastomer layer.

In particular, with the method described above, an electromechanical transducer with a disruptive strength of >40 V/μm in accordance with ASTM D 149-97a, particularly preferably >60 V/μm, most particularly preferably >80 V/μm, an electrical resistance of >1.5E10 Ohm m in accordance with ASTM D 257, preferably >1E11 Ohm m, particularly preferably >5 E12 Ohm m, most particularly preferably >1E13 Ohm m, a dielectric constant of >5 at 0.01-1 Hz in accordance with ASTM D 150-98, a layer thickness of a dielectric film (calculated as a monolayer) of <100 μm, and preferably >2 and <100 000 layers, can be produced.

The coating of the at least first part of the elastomer film with an electrode layer may be performed over the full surface area. According to a first embodiment of the process according to the invention, the at least one electrode layer may be a structured electrode layer or a segmented electrode layer. In other words, a (special) predefinable geometrical structure can only be applied in partial regions of a surface of the first part of the elastomer film. The electrode layer may for example be formed by the electrode for creating an electrical field and a terminal lug for applying a specific potential or for tapping a specific potential. By suitable dimensioning of the cross section, the geometrical structure of the electrode layer may be used as a fuse element, with which the electrical current flowing in the event of an electric breakdown sublimates the electrode, and thereby electrically deactivates this defective actuator film.

The electrode layer may preferably be applied to the first part of the elastomer layer by spraying, pouring, knife-coating, brushing, printing, vapor-depositing, sputtering and/or plasma CVD. In particular, a suitable device for applying, such as a spraying device, a printing device, a rolling device, etc., may be provided. Printing processes that can be given by way of example here are inkjet printing, flexographic printing and screen printing. An electrode layer, in particular a structured electrode layer, may be applied in an easy way to the elastomer film at least before the first folding step.

In a further embodiment, the electrode layer may be mixed with a binder. This improves the mechanical cohesion of the layers of the multilayer electromechanical transducer. Furthermore, the electrode layer may preferably be dried before the folding step.

In order to obtain an electromechanical transducer with a relatively great extensibility or a relatively great actuator effect, according to a particularly preferred embodiment of the method according to the invention the elastomer film may be pre-stretched before the application of the electrode layer. As an alternative or in addition, the elastomer film may be pre-stretched after the application of the electrode layer. The pre-stretched elastomer film may be provided with an unelastic material for the fixing of the pre-stretching. For example, a frame of an appropriate material may be applied to the elastomer film. In particular, a rigid polymer material may be used. For example, the pre-stretching may be fixed by way of printing with a rigid polymer material. The polymer material frame applied may furthermore preferably have register marks. This has the advantage that no offset can occur between the elastomer films during a downstream stacking process.

In addition, it may be provided according to a further embodiment of the method according to the invention that, before or after the fixing of the elastomer film on the folding device, the elastomer film is at least partially cut into at at least one folding edge. The cutting in may be achieved by cutting (for example ultrasonic cutting), punching or other separating methods, such as for example heated-wire cutting or a laser cutting. By at least partially cutting in a folding edge, the folding can be made easier and the occurrence of undesired beads at the edge regions can be further reduced. Moreover, an elastomer film can be folded a number of times in an easy way. For example, after fixing, the elastomer film can also be completely severed into two parts-films at at least one folding edge. Undesired beads at the edge regions can also be further reduced.

In particular, at least the folding step is repeated at least twice, preferably at least five times, particularly preferably ten times, and most particularly preferably twenty times. If, in a first application step, (only) a first part of the elastomer film is provided with an electrode layer, the application step may be repeated preferably at least five times, particularly preferably ten times, and most particularly preferably twenty times. In particular, each folding step may be followed by an application step.

Furthermore, it may be provided that the folding step is repeated at most 1 000 000 times, preferably at most 100 000 times, particularly preferably at most 10 000 times, most particularly preferably at most 5000 times and in particular most particularly preferably at most 1000 times.

It may also be provided that the application step is repeated at most 1 000 000 times, preferably at most 100 000 times, particularly preferably at most 10 000 times, most particularly preferably at most 5000 times and in particular most particularly preferably at most 1000 times.

According to a further embodiment, in the application step, a plurality of separate electrode layers may be applied to at least the first part of the elastomer layer. For example, at least two, preferably at least four, particularly preferably at least eight, and most particularly preferably at least sixteen, electrode layers may be applied. By applying a plurality of electrode layers at the same time, the manufacturing time can be further reduced. Parallel production of a plurality of electromechanical transducers is made possible.

As already described, preferably a plurality of electromechanical transducers can be produced at the same time according to the method described above. In a further method step, in particular after the (last) folding step, at least one multilayer electromechanical transducer may be detached from the rest of the elastomer film. For example, the electromechanical transducer may be punched out and/or cut out. A plurality of electromechanical transducers produced at the same time can be individually separated and brought into a desired form, for example with certain dimensions, in an easy way.

According to a further embodiment, at least two of the electromechanical transducers produced by particularly a number of folding steps may be stacked one on top of the other. It goes without saying that also more than two multilayer electromechanical transducers can be stacked one on top of the other. On account of the multilayer construction of an electromechanical transducer that is already created by folding, these transducers can be easily handled and can be re-stacked with little effort. Electromechanical transducers with a multitude of layers can be produced in an easy way.

As already described, an electromechanical transducer has at least two electrode layers lying on top of the other, with a dielectric elastomer layer arranged in between. By applying a voltage, that is to say by applying different potentials, to the two opposing electrode layers, an extension of the elastomer film lying in between can be brought about. It goes without saying that, in the case of a sensor or generator application, an extension of the elastomer film can bring about a certain voltage at the electrode layers and this can be tapped at the electrodes.

In the case of a multilayer electromechanical transducer, it is necessary that the stacked electrodes can be supplied with alternating potential. Preferably, a contacting electrode layer may be connected to first electrode layers of the electromechanical transducer, designed for applying a first electrical potential to the first electrode layers. A second contacting electrode layer may be connected to at least one second electrode layer, preferably a plurality of second electrode layers, of the electromechanical transducer, for applying a second electrical potential to the second electrode layers. In the electromechanical transducer, first electrode layers and second electrode layers may be arranged alternately. The same applies correspondingly to the tapping of voltages in the case of sensor or generator applications. In particular, the first electrode layers and the second electrode layers may be formed as essentially the same. For example, they may comprise a planar electrode area and a terminal lug for connecting the electrode area to a contacting electrode layer. Preferably, the terminal lugs of all of the first electrode layers in an electromechanical transducer may be aligned with a first same outer side of the transducer. Furthermore, the terminal lugs of all of the second electrode layers in an electromechanical transducer may be aligned with a second same outer side of the transducer, the first outer side being different from the second outer side. The two outer sides are preferably opposite outer sides.

In particular, in the case of an electromechanical transducer produced by the present method, the electrode layers have been applied to the elastomer films in such a way that they can be contacted from the sides and do not protrude beyond the edge of the dielectric film. The reason for this is that otherwise breakdowns can occur. Preferably, a safety margin may be left between the electrode and the dielectric, so that the electrode area is smaller than the dielectric area. The electrode may be structured in such a way that a conductor track is led out for electrical contacting. The electrode layers can be contacted in an easy way.

According to a further preferred embodiment of the method according to the invention, the electromechanical transducer may be encapsulated. In particular, the electromechanical transducer may be protected from external environmental influences by a reversible, extensible protective layer. For example, for the encapsulation the electromechanical transducer may be potted in a polyurethane shell and/or a silicone shell. The electromechanical transducer may be potted with elastomer materials based on synthetic elastomers, for example polyurethane elastomers, silicone elastomers, acrylate elastomers, such as EVA, fluororubber, unvulcanized rubber, vulcanized rubber, polyurethane, polybutadiene, NBR or isoprenes and/or polyvinylidene fluoride. Preference is given to using silicone elastomers. The encapsulation may be in one or two or more layers. The encapsulation may be partially or completely cured. Apart from UV curing, untriggered chemical curing and IR curing processes, purely thermal curing is preferred. Furthermore, the application of the encapsulation may in principle be performed in any way desired. A casting process may preferably be used, particularly preferably a vacuum-casting or centrifuging process.

Preferably, two elastomer films may be laminated together before further use. In addition, according to a further embodiment, the surfaces of an elastomer film may be treated in such a way that the adhesion is improved. Preferably, the elastomer film may be treated by a corona irradiation and/or a plasma treatment before the application of the electrode layer. As an alternative or in addition, the elastomer film may be treated by a corona irradiation and/or a plasma treatment after the application of the electrode layer. As an alternative or in addition, an extensible adhesive may be used. The adhesion, particularly permanent adhesion, of the layers of a multilayer electromechanical transducer to one another can be improved significantly.

A further aspect of the invention is an electromechanical transducer produced according to the method described above.

Yet a further aspect of the invention is a component comprising an electromechanical transducer described above. The component may be an electronic and/or electrical device, in particular a module, automatic device, instrument or component part, comprising the electromechanical transducer.

A further aspect of the present invention is a use of an electromechanical transducer described above as an actuator, sensor and/or generator. The electromechanical transducer according to the invention can be advantageously used in a multitude of very different applications in the electromechanical and electroacoustic sector, especially in the sectors of energy harvesting from mechanical vibrations, acoustics, ultrasound, medical diagnostics, acoustic microscopy, mechanical sensing, especially pressure, force and/or expansion sensing, robotics and/or communications technology. Typical examples thereof are pressure sensors, electroacoustic transducers, microphones, loudspeakers, vibration transducers, light deflectors, membranes, modulators for glass fiber optics, pyroelectric detectors, capacitors, control systems and “intelligent” floors, and also systems for conversion of mechanical energy, especially from rotating or oscillating motions, into electrical energy.

Yet a further aspect of the invention is a device as claimed in claim 15 for producing an electromechanical transducer. The device is designed in particular for carrying out the method described above. The device, in particular a folding device, comprises a first plate and at least one second plate. The first plate is foldable with respect to the second plate. The first plate and the second plate have a receiving surface for receiving a dielectric elastomer film. The receiving surface is designed for fixing the elastomer film on the device.

The device is, in particular, a folding device described above. An elastomer film may be arranged on a receiving surface of the folding device. The folding device is in particular of a plate form. In particular, the folding device has at least two plates. These may be movably connected to one another.

According to a preferred embodiment, the first plate is movably connected to the second plate, in particular by way of at least one hinge device. In particular, the two plates may be connected to one another in such a way that, in an initial position, the two plates form a plane and, in an end position, the first plate lies on the second plate (or vice versa). Suitable means, such as motors, actuators, control means, may be provided for moving the at least two plates.

It goes without saying that the folding device may have more than two plates, the further plates being connected for example by way of a hinge device to at least one further plate and being able to have partial receiving surfaces. Apart from a hinge device, a strip connection may also be used for example for a connection.

The receiving surface is designed for fixing, preferably reversibly fixing, the elastomer film on the folding device. According to one embodiment, the receiving surface may be designed for creating a negative pressure, for example a vacuum, in order to fix the elastomer film on the folding device. Corresponding evacuating means may be provided for this purpose. By performing the fixing preferably by negative pressure, the elastomer film can be fixed (virtually) free from folds and subsequently be folded exactly in register. The folding device is distinguished in particular by the fact that even elastomer films with a small layer thickness can be fixed reliably and (virtually) free from folds. The elastomer film may have a layer thickness of 0.1 μm to 1000 μm, preferably of 1 μm to 500 μm, particularly preferably of 5 μm to 200 μm and most particularly preferably of 10 μm to 100 μm.

After the fixing of the elastomer film, in particular on the receiving surface of the at least two plates, the elastomer film is folded, in that the first plate is folded with respect to the second plate. On account of the at least one hinge device, in particular a 180° pivoting movement can be performed, for example by the means described above. For example, the first plate may be swung onto the second plate or the second plate may be swung onto the first plate. This may take place in particular in such a way that the electrode layer is arranged essentially between the first part of the elastomer film and the second part of the elastomer film. In this state, the negative pressure in a plate can be ended. In addition, by activating a positive pressure in this plate, the pressing force/laminating process of the two parts of the elastomer film can be enhanced. Segmented introduction of the positive pressure (for example through segmented clearances in the receiving surface) allows the lamination to be carried out in a specific manner.

The features of the methods and devices can be freely combined with one another. In particular, features of the description and/or of the dependent claims may be independently inventive on their own or when freely combined with one another, even while completely or partially circumventing features of the independent claims.

There are thus a multitude of possibilities for refining and further developing the method according to the invention, the method according to the invention, the electromechanical transducer according to the invention, the component according to the invention, the use according to the invention and the device according to the invention. In this respect, reference should be made on the one hand to the patent claims arranged subordinate to the independent patent claims, on the other hand to the description of exemplary embodiments in conjunction with the drawing. In the drawing:

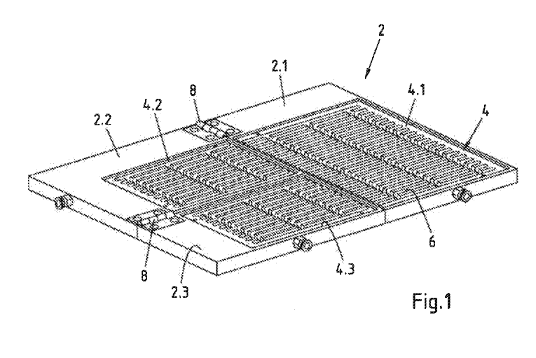

FIG. 1 shows a schematic view of an exemplary embodiment of a device for producing a multilayer electromechanical transducer,

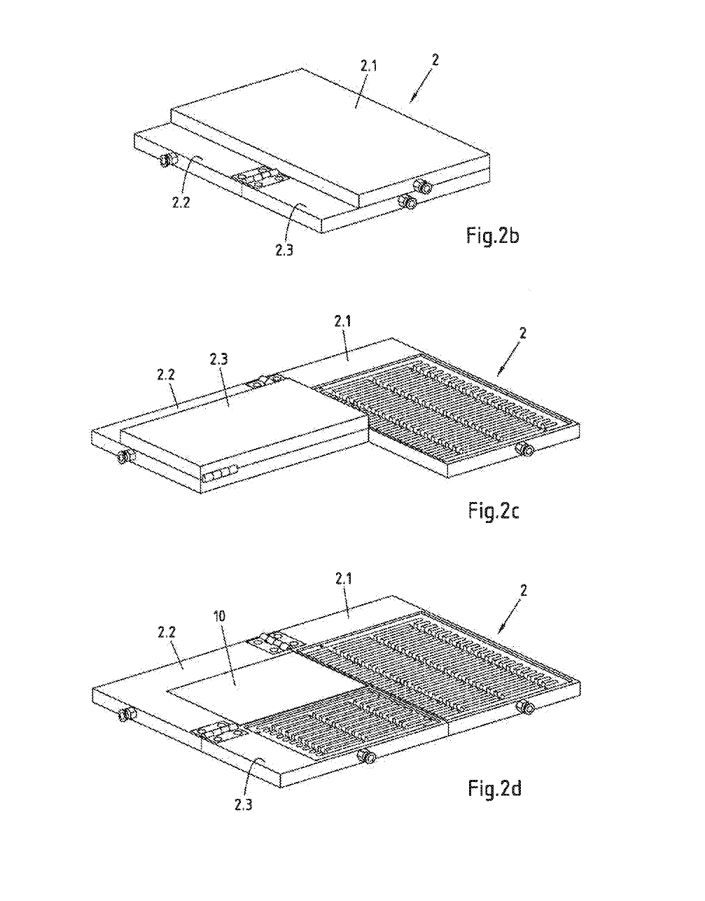

FIG. 2a shows a schematic view of the device shown by way of example in FIG. 1 in a first operating position,

FIG. 2b shows a schematic view of the device shown by way of example in FIG. 1 in a second operating position,

FIG. 2c shows a schematic view of the device shown by way of example in FIG. 1 in a third operating position,

FIG. 2d shows a schematic view of the device shown by way of example in FIG. 1 in a fourth operating position,

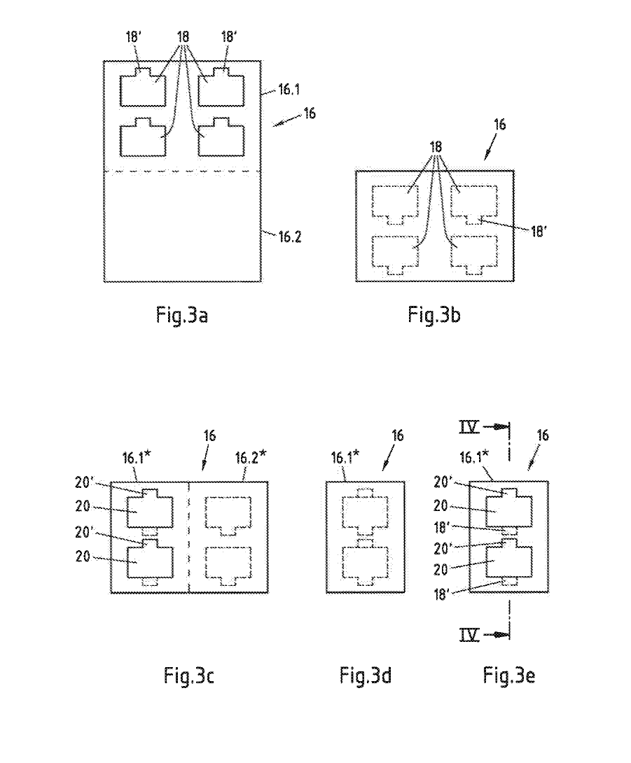

FIG. 3a shows a schematic view of an exemplary embodiment of an elastomer film after a first method step,

FIG. 3b shows a schematic view of an exemplary embodiment of an elastomer film after a further method step,

FIG. 3c shows a schematic view of an exemplary embodiment of an elastomer film after a further method step,

FIG. 3d shows a schematic view of an exemplary embodiment of an elastomer film after a further method step,

FIG. 3e shows a schematic view of an exemplary embodiment of an elastomer film after a further method step,

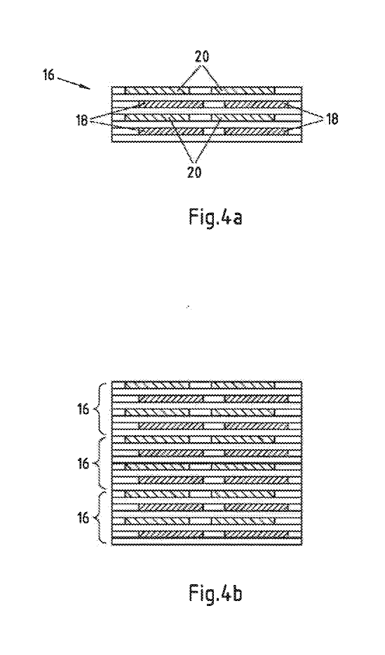

FIG. 4a shows a schematic side view of the exemplary embodiment of an electromechanical transducer shown in FIG. 3e according to sectional line IV-IV,

FIG. 4b shows a schematic side view of a plurality of electromechanical transducers as shown in FIG. 4a arranged one on top of the other,

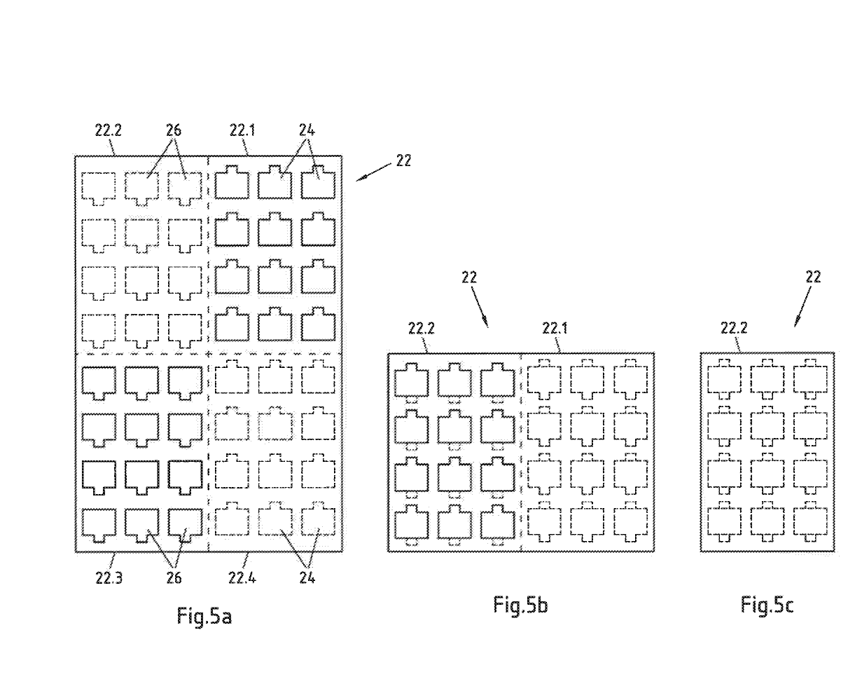

FIG. 5a shows a schematic view of a further exemplary embodiment of an elastomer film after a first method step,

FIG. 5b shows a schematic view of the further exemplary embodiment of an elastomer film after a further method step,

FIG. 5c shows a schematic view of the further exemplary embodiment of an elastomer film after a further method step,

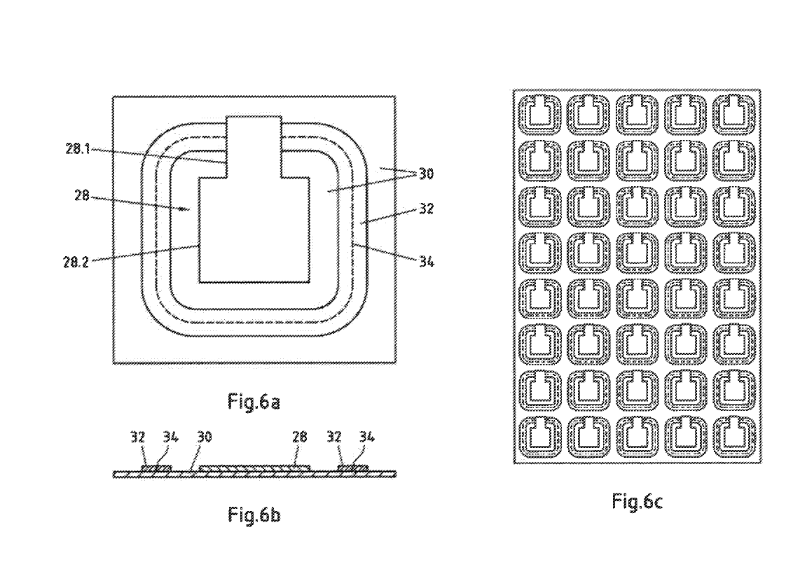

FIG. 6a shows a schematic plan view of an exemplary embodiment of a coated elastomer film,

FIG. 6b shows a schematic side view of the exemplary embodiment shown in FIG. 6a,

FIG. 6c shows a schematic view of an exemplary embodiment of an elastomer film with a plurality of segmented and separate electrode areas,

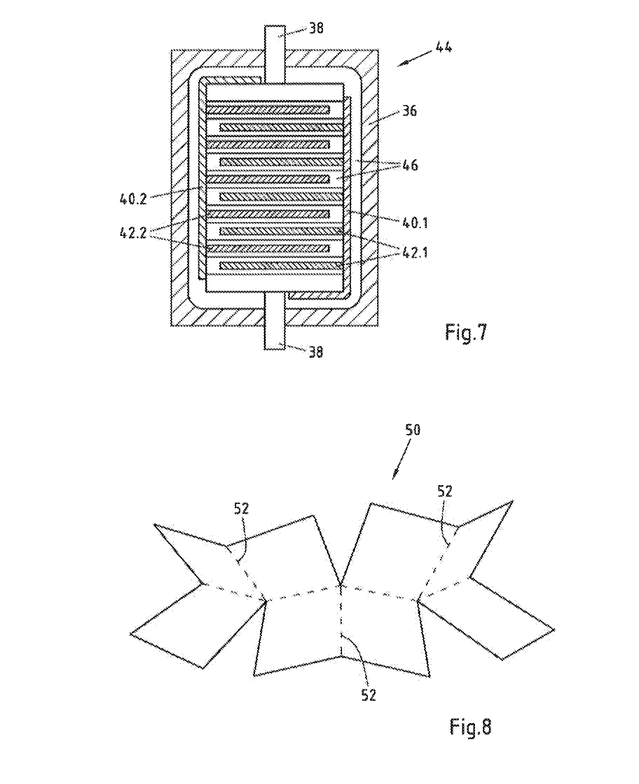

FIG. 7 shows a schematic view of an exemplary embodiment of an electromechanical transducer according to the invention, and

FIG. 8 shows a schematic view of an exemplary embodiment of an elastomer film with partially cut-into folding edges.

Hereinafter, the same designations are used for the same elements.

FIG. 1 shows a schematic view of an exemplary embodiment of a device 2 for producing a multilayer electromechanical transducer. The device 2 that is shown by way of example is, in particular, a folding device 2. The present folding device 2 comprises a first plate 2.1, a second plate 2.2 and a third plate 2.3. The second plate 2.2 is connected to the third plate 2.3 by way of a hinge device 8. The second plate 2.2 is additionally connected to the first plate 2.1 by way of a further hinge device 8.

As can also be seen from FIG. 1, the device 2 has a receiving surface 4. The receiving surface 4 is designed for receiving an elastomer film to be processed. In particular, the receiving surface 4 is formed by a recess in the device 2, in particular in the three plates 2.1, 2.2, 2.3. In the present case, the receiving surface has a rectangular form. It goes without saying that the form may be formed in any way desired according to other variants of the invention.

The first plate 2.1 has a first partial receiving surface 4.1, the second plate 2.2 has a second partial receiving surface 4.2 and the third plate 2.2 has a third partial receiving surface 4.3. The three partial receiving surfaces 4.1, 4.2, 4.3 form the overall, contiguous receiving surface 4.

In order to fix an elastomer film on the folding device 2, recesses 6 are provided in the receiving surface. In particular, a plurality of grooves 6 are provided. A negative pressure, in particular a vacuum, can be created by means of vacuum-creating means (not shown), so that an elastomer film arranged on the receiving surface 4 can be fixed. In particular, this allows an elastomer film to be fixed on the folding device 2 in an easy way without folds, creases or the like.

The way in which the folding device 2 works is explained below by way of example by means of FIGS. 2a to 2d, which show the device 2 in various operating positions.

FIG. 2a shows the device 2 in a first operating position or in a starting or initial position. In this operating position, all of the plates 2.1, 2.2, 2.3 have a level plane. In particular, an elastomer film 10 may be arranged on the receiving surface 4. After the arrangement, a negative pressure may be created in the recesses 6 of the receiving surface 4, in order to fix the film 10. In the present case, a plurality of electrode layers 12 have already been applied to the elastomer film 10, for the sake of a better view only indicated here by the designation 12. A more detailed description follows. It can also be seen that the form of the elastomer film 10 corresponds essentially to the form of the receiving surface 4.

FIG. 2b shows the device 2 in a second operating position. In this operating position, the first plate 2.1 has been folded or swung onto the second and third plates 2.2, 2.3 by a (180°) pivoting movement. In this operating position, the vacuum created in the first partial receiving surface 4.1 is ended. It is preferred that a positive pressure can be additionally created. The first part of the elastomer film 10 is folded or swung over the second and third parts of the elastomer film exactly in register.

In a further operating position that is not shown, the first plate 2.1 is pivoted/swung back into the initial position. The folded elastomer film 10 is now only arranged and still fixed on the partial receiving surface 4.2 and on the partial receiving surface 4.3. This is a two-layer arrangement.

In the third operating position, shown in FIG. 2c, the third plate 2.3 has been folded/swung onto the second plate 2.2 by a (180°) pivoting movement. In this operating position, the vacuum created in the partial receiving surface 4.3 is ended. With preference, here too a positive pressure can be additionally created. The third part of the elastomer film 10 is swung or folded over the second part of the elastomer film exactly in register.

In a fourth operating position (FIG. 2d) or end position of the device 2, the third plate 2.3 has been pivoted/swung back into the initial position. The folded elastomer film 10 is now only arranged on the second partial receiving surface 4.2. This is a four-layer arrangement or a four-layer electromechanical transducer. A multilayer electromechanical transducer can be produced by the folding device 2 in an easy way. It goes without saying that further steps can additionally follow, as will be explained.

FIGS. 3a to 3e show on the basis of an elastomer film 16 various method steps of an exemplary embodiment of a method for producing electromechanical transducers according to the invention.

FIG. 3a shows an elastomer film 16 with a first part 16.1 and a second part 16.2. In a previous application step (not shown), in the present case four separate electrode layers 18 have been applied to the first part 16.1 of the elastomer film. In particular, four structured electrodes 18 have been applied. For example, the structured electrodes 18 may have been sprayed on.

In a folding step, the first part 16.1 is placed onto the second part 16.2, in particular by a pivoting movement by means of the device 2 described above. In FIG. 3b it can be seen that the electrode layers 18 lie with the terminal lugs 18′ inward after the folding step (indicated by hatching), that is to say between the two parts 16.1, 16.2 of the elastomer film 16.

The folded elastomer film 16* is subsequently divided into a further first part 16.1* and a further second part 16.2*. In the present case, two further electrode layers 20 are applied to the further first part 16.1*. The electrode layer 20 differs from an electrode layer 18 by the arrangement of the electrode terminal lug 20′ in relation to another outer side of the elastomer film. In particular, the electrode layer 20 is applied essentially over the electrode layer 18. In the present case, just the terminal lugs 18′, 20′ do not lie one on top of the other.

In a further folding step, the further second part 16.2* is placed onto the further first part 16.1*, in particular by a pivoting movement. In FIG. 3d it can be seen that the electrode layers 18, 20 lie on the inside.

Two further electrode layers 20 are subsequently applied to the upper surface of the part 16.1*. In a corresponding way, two further electrode layers may be applied on the underside. In particular, two four-layer electromechanical transducers are produced by this method.

FIG. 4a shows a schematic view of the cross section through the two four-layer electromechanical transducers shown in FIG. 3e corresponding to sectional line IV-IV. It can be seen that the terminal lugs 18′ of the first electrode layers 18 point to a different side than the terminal lugs 20′ of the further electrode layers 20. The electromechanical transducers may for example be individually separated in a further step by detachment, e.g. punching.

FIG. 4b shows an exemplary embodiment of the electromechanical transducers shown in FIG. 4a, three arrangements 16 being arranged one on top of the other. In particular, multilayer transducers produced by the method described above can be stacked more easily on account of the increased layer thickness, and accompanying increased stability, in comparison with individual layers.

FIGS. 5a to Sc show various method steps of a further exemplary embodiment of a method for producing electromechanical transducers according to the invention. Hereinafter, essentially only the differences from the exemplary embodiment shown in FIGS. 3a to 3e are explained, and reference is otherwise made to the statements made above.

The main difference from the previous exemplary embodiment is that the entire elastomer film 22 has already been provided with all of the electrode layers 24, 26 in a single application step. Here, the electrode layers 24, 26 have been applied in such a way that, after all of the folding steps, in each case at least four electrode layers 24, 26 lie essentially one on top of the other.

In a first folding step, the parts 22.1, 22.2 are folded/placed onto the parts 22.3, 22.4 (FIG. 5b) and, in a further folding step, the part 22.2 is placed onto the part 22.1. A plurality of multilayer electromechanical transducers are produced in parallel.

FIG. 6a shows a further exemplary embodiment of a plan view of a coated elastomer film 30 comprising a segmented electrode layer 28. In the present case, the electrode layer 28 comprises a rectangular electrode 28.2 and an electrode terminal lug 28.1 aligned with an outer side.

In the present exemplary embodiment, the elastomer film 30 has been pre-stretched together with the (extensible) electrode layer 28. The pre-stretching has been fixed by applying a frame 32 of a rigid material, e.g. a polymer material. The frame also has a detaching contour 34, in particular a punching contour 34, in order to detach the electromechanical transducer along this contour 34 in a subsequent working step without impairing the pre-stretching.

FIG. 6b shows the exemplary embodiment described above in a side view. It can be seen that the electrode layer 28 and the plastic frame 32 have been applied to the particularly pre-stretched elastomer film 30.

As can be taken from the schematic illustration of FIG. 6c, an elastomer film may have a multitude of the structures described above. This makes it possible to reduce the manufacturing time significantly by parallel processing.

In FIG. 7, a schematic view of an electromechanical transducer 44 according to a preferred embodiment of the present invention is depicted. The electromechanical transducer 44 represented has alternately a layer of elastomer film 46 and an electrode layer 42.1, 42.2. Here, first electrode layers 42.1, designed for applying a first electrical potential, and second electrode layers 42.2, designed for applying a second electrical potential, are alternately arranged. All of the terminal lugs of the first electrode layers 42.1 are aligned with a first outer side, while all of the terminal lugs of the second electrode layers 42.2 are aligned with another outer side, in the present case an opposite outer side.

This makes it possible to connect the first electrode layers 42.1 to a common contacting electrode 40.1, so that the same electrical potential can be applied to all of the first electrode layers 42.1, and to connect the second electrode layers 42.2 to a common contacting electrode 40.2, so that a further same electrical potential can be applied to all of the second electrode layers 42.2. Furthermore, in the present case the electromechanical transducer 44 is embedded in a potting material 36 as protection from external influences. In particular, the transducer is potted in a polyurethane shell 36 and/or a silicone shell 36.

Finally, FIG. 8 shows by way of example an elastomer film 50 with partially cut-into folding edges 52. This makes repeated folding of the elastomer film 52 possible in an easy way. A folding device suitable for the example represented may comprise eight plates arranged movably in relation to one another.

1.-15. (canceled)

16. A method for producing at least one multilayer electromechanical transducer (44), comprising:
providing at least one dielectric elastomer film (10, 16, 22, 30, 46),
applying at least one electrode layer (12, 18, 20, 24, 26, 28, 42) to at least one first part (16.1, 16.4, 22.1) of the elastomer film (10, 16, 22, 30, 46) in an application step,
arranging the elastomer film (10, 16, 22, 30, 46) on a receiving surface (4) of a folding device (2), the folding device (2) having a first plate (2.1) and at least one second plate (2.2),
fixing the elastomer film (10, 16, 22, 30, 46) on the receiving surface (4), and
folding the first part (16.1, 16.4, 22.1) of the elastomer film (10, 16, 22, 30, 46) onto a further part (16.2, 16.3, 22.3) of the elastomer film (10, 16, 22, 30, 46) in a folding step by folding the first plate (2.1) with respect to the second plate (2.2) in such a way that the electrode layer (12, 18, 20, 24, 26, 28, 42) is arranged between the first part (16.1, 16.4, 22.1) of the elastomer film (10, 16, 22, 30, 46) and the second part (16.2, 16.3, 22.3) of the elastomer film (10, 16, 22, 30, 46).

17. The method as claimed in claim 16, characterized in that
the first plate (2.1) is movably connected to the second plate (2.2),
the first plate (2.1) and the second plate (2.2) being connected in particular by way of a hinge device (8).

18. The method as claimed in claim 16, characterized in that
the electrode layer (12, 18, 20, 24, 26, 28, 42) is mixed with a binder, and/or
the electrode layer (12, 18, 20, 24, 26, 28, 42) is dried before the folding step.

19. The method as claimed in claim 16, characterized in that
the elastomer film (10, 16, 22, 30, 46) is pre-stretched before the application of the electrode layer (12, 18, 20, 24, 26, 28, 42),
the pre-stretched elastomer film (10, 16, 22, 30, 46) being provided with an unelastic material for the fixing of the pre-stretching,
and/or
the elastomer film (10, 16, 22, 30, 46) being pre-stretched after the application of the electrode layer (12, 18, 20, 24, 26, 28, 42),
the pre-stretched elastomer film (10, 16, 22, 30, 46) being provided with an unelastic material for the fixing of the pre-stretching.

20. The method as claimed in claim 16, characterized in that, before or after the fixing of the elastomer film (10, 16, 22, 30, 46) on the folding device (2), the elastomer film (10, 16, 22, 30, 46) is at least partially cut into at a folding edge (52).

21. The method as claimed in claim 16, characterized in that the application step and/or the folding step is repeated at least twice, preferably at least five times, particularly preferably ten times, and most particularly preferably twenty times.

22. The method as claimed in claim 16, that, in the application step, a plurality of separate electrode layers (12, 18, 20, 24, 26, 28, 42) are applied to at least the first part (16.1, 16.4, 22.1) of the elastomer layer (10, 16, 22, 30, 46).

23. The method as claimed in claim 16, characterized in that, after the folding step, a plurality of folded elastomer films are stacked to multiply the number of layers.

24. The method as claimed in claim 16, characterized in that, after the folding step/stacking step, at least one multilayer electromechanical transducer (44) is detached, the detachment being performed in particular by punching out and/or cutting out.

25. The method as claimed in claim 24, characterized in that
a first contacting electrode layer (40.1) is connected to first electrode layers (42.1) of the electromechanical transducer (44), designed for applying and/or tapping a first electrical potential to/from the first electrode layers (42.1),
a second contacting electrode layer (40.2) is connected to second electrode layers (42.2) of the electromechanical transducer (44), for applying and/or tapping a second electrical potential to/from the second electrode layers (42.2),
first electrode layers (42.1) and second electrode layers (42.2) being arranged alternately in the electromechanical transducer (44).

26. The method as claimed in claim 25, characterized in that
the electromechanical transducer (44) is encapsulated,
the electromechanical transducer (44) being potted in a polyurethane shell (36) and/or a silicone shell (36) for the encapsulation.

27. The method as claimed in claim 16, characterized in that
the elastomer film (10, 16, 22, 30, 46) is treated by a corona irradiation and/or a plasma treatment before the application of the electrode layer (12, 18, 20, 24, 26, 28, 42),
and/or
the elastomer film (10, 16, 22, 30, 46) is treated by a corona irradiation and/or a plasma treatment after the application of the electrode layer (12, 18, 20, 24, 26, 28, 42).

28. An electromechanical transducer (44) produced according to the method as claimed in claim 16.

29. A component comprising an electromechanical transducer (44) as claimed in claim 28.

30. A use of an electromechanical transducer (44) as claimed in claim 28 as an actuator, sensor and/or generator.

31. A device (2) for producing an electromechanical transducer (44), in particular for carrying out the method as claimed in claim 16, comprising:
a first plate (2.1),
at least one second plate (2.2),
the first plate (2.1) being foldable with respect to the second plate (2.2),
the first plate (2.1) and the second plate (2.2) having a receiving surface (4) for receiving a dielectric elastomer film (10, 16, 22, 30, 46),
the receiving surface (4) being designed for fixing the elastomer film (10, 16, 22, 30, 46) on the device (2).
